(19) United States
(12) Patent Application Publication
(10) Pub. No.: US 2016/0321486 A1
(43) Pub. Date: Nov. 3, 2016

(54) ELECTRONIC DEVICE MANAGEMENT USING A LABEL PROVIDING MANAGEMENT DATA

(71) Applicant: Lenovo Enterprise Solutions (Singapore) Pte. Ltd., Singapore (SG)

(72) Inventors: CheKim Chhuor, Shanghai (CN); Zhen De Fu, Shanghai (CN); Shunrong Hu, Shanghai (CN); Wen Wei Tang, Shanghai (CN)

(21) Appl. No.: 15/142,086

(22) Filed: Apr. 29, 2016

(30) Foreign Application Priority Data
Apr. 30, 2015 (CN) 2015102200399

(51) Int. Cl. G06K 7/10; G06K 19/06; H05K 7/14

(52) U.S. Cl. CPC G06K 7/10861; H05K 7/1488; H05K 7/1498; G06K 19/06037

(57) ABSTRACT

A rack used for managing electronic devices, an electronic device, and related methods are provided. The rack includes a mounting assembly defining a space used for accommodating an electronic device, and a label associated with the mounting assembly, wherein the label including management data related to at least one of the rack, the mounting assembly, and the electronic device. The electronic device includes a label reader configured to acquire information from a label associated with a mounting assembly of a rack, and a processor configured to determine management data based on the information acquired from the label.

### CROSS-REFERENCE TO RELATED APPLICATIONS

This application claims priority under 35 U.S.C. §119 from Chinese Patent Application No. 2015102200399, filed on Apr. 30, 2015, the entire text of which is specifically incorporated by reference herein.

### BACKGROUND

1. Field of the Invention

The present invention generally relates to electronic device management, and more particularly relates to a rack for electronic device management, an electronic device, and related methods.

2. Background of the Related Art

Following the continuous breakthroughs of the computer industry, a large number of electronic devices are being widely used. The electronic devices, for example, may include servers, routers, exchangers, switchers, monitors, storage devices, power supply devices, and the like. To place and manage the electronic devices efficiently, a large number of racks are used. A rack may generally be used to place one or more electronic devices, and is often used in a data center environment such as a machine room, a control center, a monitoring center, a network wiring room, and a floor wiring room. The use of racks solves problems in electronic device applications, such as high density heat dissipation, attachment and management of a large number of cables, high-capacity power distribution, and compatibility with electronic devices from different manufacturers, so that the data center can run in a stable environment.

In some situations, changes in the electronic devices in the data center generally occur over time, and therefore, the electronic devices may need to be repositioned and managed frequently. For example, to maintain servers in a machine room, the servers on a certain rack may be periodically or frequently removed or replaced. In this case, a worker in the machine room needs to take down the server from the rack, and after maintenance, find the rack to which the server belongs and the original position of the server on the rack, so as to put the server back. In another example, when a server has failed, a worker in the machine room needs to correctly and quickly find the failed server from among a large number of servers on a large number of racks, so as to repair or replace the failed server. It can be seen that a worker in the machine room may have to spend a lot of time or energy searching for the needed server from among a large number of servers on a large number of racks in the machine room, which significantly increases the manual processing cost, reduces the working efficiency, and increases the possibility of errors. Therefore, efficiently managing racks in a data center and electronic devices on the racks is an important objective.

### BRIEF SUMMARY

One embodiment of the present invention provides a rack comprising a mounting assembly defining a space used for accommodating an electronic device, and a label associated with the mounting assembly, the label including management data related to at least one of the rack, the mounting assembly, and the electronic device.

Another embodiment of the present invention provides a method comprising providing a label associated with a mounting assembly of a rack, and the mounting assembly defining a space used for accommodating an electronic device, wherein the label includes management data extractable by the electronic device, and wherein the management data is related to at least one of the rack, the mounting assembly, and the electronic device.

A further embodiment of the present invention provides an electronic device comprising a label reader configured to acquire information from a label associated with a mounting assembly of a rack, the mounting assembly defining a space used for accommodating the electronic device. The electronic device further comprises a processor configured to determine management data based on the information acquired from the label, wherein the management data is related to at least one of the rack, the mounting assembly, and the electronic device.

### BRIEF DESCRIPTION OF THE SEVERAL VIEWS OF THE DRAWINGS

The following detailed description with reference to the accompanying drawings is provided to illustrate various features and advantages of the present invention. In the accompanying drawings, several embodiments of the present invention are shown as non-limiting examples and should not be interpreted as limiting the scope of the invention.

FIG. 1 is a schematic diagram of a rack according to an embodiment of the present invention.

FIG. 2 is a schematic diagram of a part of a support component of a rack according to an embodiment of the present invention.

FIG. 3 is a schematic diagram of a label arrangement according to an embodiment of the present invention.

FIG. 4 is a flowchart of a method for providing a label according to an embodiment of the present invention.

FIG. 5 is a block diagram of an electronic device according to an embodiment of the present invention.

FIG. 6 is a block diagram of an electronic device according to another embodiment of the present invention.

FIG. 7 is a flowchart of a method executed by an electronic device according to an embodiment of the present invention.

FIG. 8 is a block diagram of an apparatus in an electronic device according to an embodiment of the present invention.

FIG. 9 is a block diagram of a computer system that can be used in combination with an embodiment of the present invention.

In the accompanying drawings, the same or corresponding reference numerals represent the same or corresponding parts.

### DETAILED DESCRIPTION

One embodiment of the present invention provides a rack comprising a mounting assembly defining a space used for accommodating an electronic device, and a label associated with the mounting assembly, the label including management data related to at least one of the rack, the mounting assembly, and the electronic device.

Another embodiment of the present invention provides a method comprising providing a label associated with a mounting assembly of a rack, and the mounting assembly defining a space used for accommodating an electronic device, wherein the label includes management data extractable by the electronic device, and wherein the management data is related to at least one of the rack, the mounting assembly, and the electronic device.

A further embodiment of the present invention provides an electronic device comprising a label reader configured to acquire information from a label associated with a mounting assembly of a rack, the mounting assembly defining a space used for accommodating the electronic device. The electronic device further comprises a processor configured to determine management data based on the information acquired from the label, wherein the management data is related to at least one of the rack, the mounting assembly, and the electronic device.

It may be understood from the following descriptions that, according to the embodiments of the present invention, by setting a label including management data for a rack, the management data may be provided automatically to an electronic device mounted on the rack. In this way, the rack has advantages such as a convenient manner of implementation and a low cost of manufacturing. Meanwhile, the electronic device can quickly and conveniently acquire the associated management data, so that a user (for example, a worker in a data center environment) may perform efficient management on the electronic device. Therefore, according to the solutions of the embodiments of the present invention, the manual processing cost may be effectively reduced, the working efficiency may be increased, and the probability of errors may also be reduced.

Embodiments of the present invention are described below in more detail with reference to the accompanying drawings. Although certain embodiments are shown in the accompanying drawings, it should be understood that the present invention may be implemented in various forms, and should not be limited by the embodiments described herein. In contrast, the various embodiments are provided to make the disclosure more thorough and complete, and to be able to completely convey the scope of the disclosure to persons skilled in the art.

Mechanisms and principles of embodiments of the present invention will be described in detail in the following. Unless otherwise specified, the term “based on” used in the following text and the claims means “at least partially based on”. The terms “comprise” and “include” mean non-exclusively comprising and including, that is, “include but not limited to”. The term “multiple” means “two or more”. The term “one embodiment” means “at least one embodiment”. The term “another embodiment” means “at least one other embodiment”. Definitions of other terms will be provided in the following descriptions.

As used herein, the term “rack” may refer to any form of a shelf or cabinet that can accommodate one or more electronic devices. In the context of the present invention, the term “rack” may be used interchangeably with the term “cabinet.” In embodiments of the present invention, the rack may have an enclosed structure or a non-enclosed structure, and may also be implemented in multiple specific forms. For example, the rack may be implemented as a frame including four supporting components (for example, four columns), or may be a non-enclosed cabinet including three supporting components (for example, two side plates and a back plate), or may also be implemented as an enclosed cabinet including three supporting components (for example, two side plates and a back plate) and a door. In addition to the supporting components, the rack may also include a top portion, for example, the rack may be implemented as a rectangular frame and a top plate. Furthermore, the rack may further include a bottom portion, for example, it may be implemented as a rectangular frame and a bottom plate. Persons skilled in the art will understand that the structure of the cabinet may be designed according to specific requirements of systems or scenarios, and the above examples are merely used for illustration, instead of limiting the scope of the present invention.

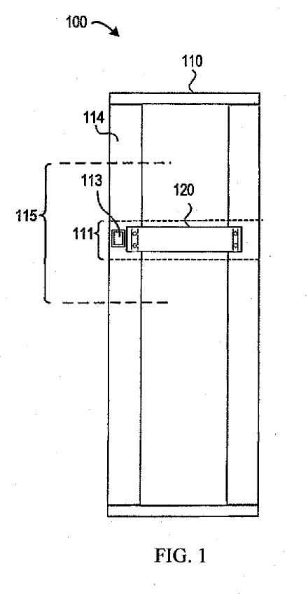

FIG. 1 is a schematic diagram 100 of a rack according to an embodiment of the present invention. A rack is used to accommodate one or more electronic devices, and prior to the present invention, the rack has not transmitted any information with the electronic devices. Once the electronic device is mounted on the rack or has any subsequent changes, a worker in a data center may spend a lot of time or energy to record information of the electronic device such as location information, an IP address, a media access control (MAC) address, a maintainer, and an owner. This manner of manually recording information may cause problems such as an increase in manual processing cost, reduced working efficiency, and a high error rate. It will be understood through the following descriptions that these problems may be effectively solved by using the rack and the electronic device according to one or more embodiments of the present invention.

FIG. 1 shows a rack 110 and an electronic device 120 mounted on the rack 110. As shown, the rack 110 includes a mounting assembly 111 and a label 113. The mounting assembly 111 defines a space used for accommodating the electronic device 120. Optionally, the mounting assembly 111 may correspond to a “rack unit” (RU), for example, one mounting assembly may correspond to one RU. The mounting assembly 111 may include one or more components used for mounting the electronic device, and the one or more components may be disposed on a supporting component of the rack, and may also be disposed outside the supporting component.

In an embodiment according to the present invention, the mounting assembly 111 may, for example, include a component provided with one or more holes, so as to fix the electronic device to a corresponding RU of the rack. Specifically, a corresponding hole on the outer side of the electronic device may be aligned with the hole included in the mounting assembly 111, and the aligned holes are processed by using a fastener (for example, a bolt and a nut), so as to fix the electronic device to the rack. FIG. 1 schematically shows a manner of fixing an electronic device 120, such as a server, to the rack 110 by using the mounting assembly 111 including the component provided with multiple holes. Furthermore, the component provided with one or more holes of the mounting assembly 111 may be implemented on the supporting component of the rack, for example, on a column or a side plate. Alternatively, the component provided with one or more holes of the mounting assembly 111 may also be disposed outside the supporting component and connected to the supporting component.

Alternatively or additionally, in another embodiment, the mounting assembly 111 may, for example, include one or more slide rails. For a rack having a side plate, the slide rail may be disposed on the side plate of the rack. For a rack merely having columns without any side plate, the slide rail may be disposed at the side surface of the rack in a manner of being perpendicular to the columns, and two ends of the slide rail are respectively connected to two columns at the side surface. After the electronic device is placed on the slide rail, the electronic device may be put into the space defined by the mounting assembly 111, so as to mount the electronic device to the corresponding RU of the rack.

Alternatively or additionally, in another embodiment, the mounting assembly 111 may include a tray used for bearing the electronic device. The tray may be disposed based on the supporting component of the rack, and may also be disposed according to other suitable manners. After the electronic device is placed on the tray, the electronic device may be put into the space defined by the mounting assembly 111, so as to mount the electronic device to the corresponding RU of the rack.

It should be understood that, the above examples are provided for the purpose of disclosing various embodiments, and are not intended to limit the scope of the present invention. Persons skilled in the art may implement the mounting assembly 111 of the rack 110 in any other suitable manner.

The label 113 of the rack 110 is associated with the mounting assembly 111 and stores management data, and the management data is related to at least one of the rack, the mounting assembly, and the electronic device. According to the embodiment of the present invention, the label may include a near field communication (NFC) label, a radio frequency identification (RFID) label, a two-dimensional code, a bar code and/or any other label in a suitable form. According to the embodiment of the present invention, the management data may include at least one of the following: an identifier, a location, a maintainer, an IP address, a MAC address, a suggested power limitation, a suggested input/output (I/O) throughput limitation, a suggested thermal protection threshold, and any other suitable data. In one embodiment of the present invention, the management data may include an identifier of the rack, the mounting assembly and/or the electronic device, such as, a rack name, an RU number, and an electronic device name. The RU number may indicate which RU on the rack, for example, “RU1” is an example of the RU number, and it may indicate the 1^{st} RU on the rack. Similarly, “RU2” may indicate the 2^{nd} RU on the rack, and so on. The management data may also include a location of the rack, the mounting assembly and/or the electronic device, for example, a nation, a city, an area, a machine room place and the like where the rack, the mounting assembly and/or the electronic device is located. The management data may also include a maintainer (responsible person, group or entity) of the rack, the mounting assembly and/or the electronic device. The management data may also include an IP address, a MAC address, a suggested power limitation, a suggested I/O throughput limitation, a suggested thermal protection threshold, or any other suitable data. In addition, the management data may also include information about the label, such as a first creation time, an update time, and a version. It should be understood that the examples of the management data are all optional and schematic, and none of these specific examples are not required. Persons skilled in the art may use many types of other suitable management data within the scope of the present invention.

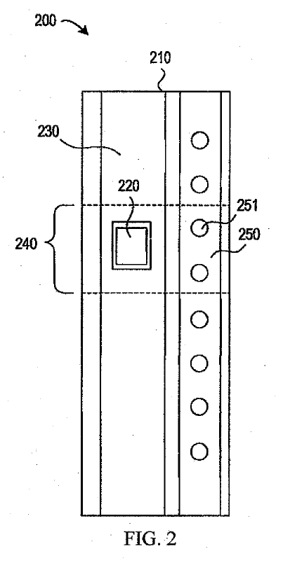

According to various embodiment of the present invention, the label 113 associated with the mounting assembly 111 may be disposed at any suitable position on the rack 110. In one embodiment, the rack 110 may include a supporting component 114, and the label 113 may be arranged in relation to a part of the supporting component 114. For example, the label 113 may be arranged on one or more columns of the rack 110, or may be arranged on one or more side plates of the rack 110. Alternatively, the rack 110 may include a stripe, and the label 113 may be arranged in relation to a part of the stripe. The stripe may be, for example, a stripe shaped component parallel to the supporting component. The stripe may be disposed on the supporting component, and may also be disposed outside the supporting component. In an embodiment according to the present invention, the stripe may be, for example, a component used for decorating the rack, a component used for identifying the RU of the rack, a component used for assisting the supporting component, or any other suitable component. More details may be described in reference to the embodiment shown in FIG. 2.

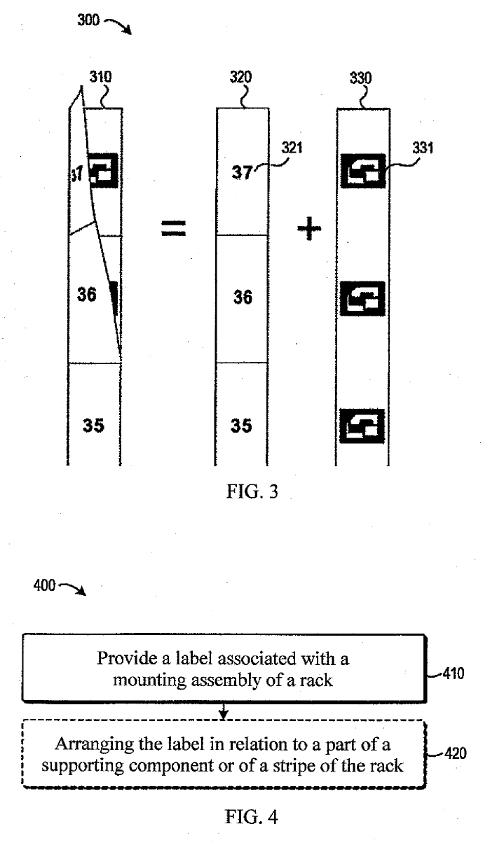

Additionally or alternatively, an identifier may be used to mark the part of the supporting component 114 or the part of the stripe, and the label 113 may be arranged together with the identifier. More details may be described in reference to the embodiment shown in FIG. 3.

It should be understood that the above examples are provided merely for the purpose of disclosing various embodiments, and are not intended to limit the scope of the present invention. For example, persons skilled in the art may, rather than dispose the label 113 on the rack 110, dispose the label 113 at a suitable position outside the rack 110, such as a wall near the rack 110, a partition plate between the rack 110 and another rack, and the like.

It can be understood through the above descriptions that, in the rack according to the embodiment of the present invention, by disposing the label including the management data, the management data may be provided to the electronic device that is going to be mounted or has been mounted on the rack, so that a user manages the electronic device. Therefore, the rack according to the present invention can support efficient management of the electronic device on the basis of convenient implementation and low cost. Further advantages of various embodiments of the present invention will be discussed in reference to embodiments shown in FIG. 2 and FIG. 3.

FIG. 2 is a schematic diagram 200 of a portion 210 of a supporting component of a rack according to an embodiment of the present invention. The portion 210 of the supporting component of the rack shown in FIG. 2 corresponds to a portion 115 of the supporting component 114 of the rack 110 shown in FIG. 1. As shown in FIG. 2, a mounting assembly 240 of the rack is schematically disposed on the portion 210 of the supporting component, and the mounting assembly 240 defines a space used for accommodating an electronic device. As shown, the mounting assembly 240 includes a component 250 provided with multiple holes 251. Moreover, a stripe 230 is disposed on the portion 210 of the supporting component, and the label 220 is arranged on the stripe 230, where the label 220 is associated with the mounting assembly 250 and includes management data.

In the embodiment shown in FIG. 2, by disposing the label on the stripe, the rack may be manufactured at a low cost, and convenient disposition of the label may also be implemented. For example, the stripe provided with the label may be mounted on a conventional rack, and the original structure of the rack does not need to be changed. For another example, for a rack that has been provided with a label, when the label needs to be updated, the update of the label may be implemented quickly and conveniently by mounting a stripe provided with a new label on the rack, for example, shielding the original label by using the stripe, or by using another suitable manner.

It should be understood that, the embodiment shown in FIG. 2 is schematic, and is not intended to limit the scope of the present invention. For example, when the label is arranged, persons skilled in the art may implement the arrangement in many manners within the scope of the present invention.

FIG. 3 is a schematic diagram of a label arrangement according to an embodiment of the present invention. As shown, a portion 310 of a supporting component or stripe is marked by using an identifier 321, where a label 331 is arranged together with the identifier 321. Specifically, the portion 310 of the supporting component or stripe is illustrated as being divided into two sub-components 320 and 330, where the sub-component 330, for example, may be implemented on the back side of the sub-component 320. It should be understood that the embodiment shown in FIG. 3 is merely illustrative, and is not intended to limit the scope of the present invention. A person skilled in the art may implement the portion 310 of the supporting component or stripe in many other suitable manners with the label and the identifier arranged together. For example, in an alternative embodiment, the sub-component 330 and the sub-component 320 may be disposed side by side.

The sub-component 320 may include one or more identifiers, as shown by the numbers “35”, “36”, and “37” in FIG. 3. These identifiers may be used for identifying the mounting assembly associated with the label, for example, identifying an RU corresponding to the mounting assembly. In FIG. 3, the identifier 321 on the sub-component 320 may be used to identify the 37^{th} RU. According to various embodiments of the present invention, the sub-component 320 may be implemented in many manners, for example, the sub-component 320 may be made with any suitable material that can carry the identifier, such as adhesive tape, note paper, and plastic.

The sub-component 330 may include one or more labels, and these labels are respectively associated with one or more mounting assemblies. For example, multiple mounting assemblies are provided on the rack, for example, the Pt mounting assembly to the 40^{th} mounting assembly, where the label 331 is associated with the 37^{th} mounting assembly, and the identifier 321 identifies the 37^{th} RU corresponding to the 37^{th} mounting assembly. In this case, the label 331 and the identifier 321 may be disposed together in many manners. In one embodiment, when the label 331 is an NFC label or an RFID label, the label 331 may be disposed at any position on the back side of the identifier 321, and this disposition process may be performed by, for example, adhering, or other manners. As an alternative solution, regardless whether the label 331 is an NFC/RFID label or a two-dimensional code/bar code, the label 331 may be disposed at any position on the front side of the identifier 321, or the label 331 may also be disposed at the lateral side of the identifier 321, and the two may be closely adjacent to each other or have a predetermined distance kept there-between.

In the embodiment shown in FIG. 3, by disposing the label and the identifier together, it is helpful for the user to quickly position, by using the identifier, a mounting assembly associated with the label, thereby being convenient to position a corresponding electronic device. Therefore, user experience may be further improved and working efficiency may be increased.

FIG. 4 is a flowchart of a method 400 for providing a label according to an embodiment of the present invention. In the embodiment shown, a label is associated with a mounting assembly of a rack. Optionally, the rack may be, for example, the rack 110 shown in FIG. 1, or another suitable rack that can implement one or the embodiments of the present invention.

In step S410, the method provides a label associated with a mounting assembly of a rack.

According to one embodiment of the present invention, the mounting assembly of the rack defines a space used for accommodating an electronic device. The label associated with the mounting assembly includes management data extractable by the electronic device, and the management data is related to at least one of the rack, the mounting assembly, and/or the electronic device.

According to another embodiment of the present invention, the label may include an NFC label, an RFID label, a two-dimensional code, a bar code and/or any other label in a suitable form. In an embodiment, the provided label may be an NFC label or an RFID label, and the NFC label or RFID label may include management data. According to the embodiment of the present invention, the management data may include an identifier, a location, a maintainer, an IP address, an MAC address, a suggested power limitation, a suggested I/O throughput limitation, a suggested thermal protection threshold, or any other suitable data of the rack, the mounting assembly and/or the electronic device. In the embodiment according to the present invention, the management data may also include information about the label, such as a first creation time, an update time, and a version. The management data may undergo predetermined encoding or other related pre-processing. The NFC label or RFID label may, in response to receiving a signal from a label reader, transmit the management data to the label reader of the electronic device by the signal. The electronic device may acquire the management data based on the received signal, for example, acquire the management data by executing a decoding operation on the received signal, where the management data may have been encoded at the time of, or before, being written into the NFC label or RFID label. The method of writing the management data into the NFC label or the RFID label may be implemented by any suitable technology that exists currently or becomes known in the future.

In another embodiment, the provided label may include a two-dimensional code, such as a bar code. The two-dimensional code may include the management data, and present the management data as a certain pattern, and the pattern may have one or more features corresponding to the management data. In this embodiment, the label reader of the electronic device may acquire an image of the two-dimensional code or the bar code, extract the feature from the image, and determine the management data based on the extracted feature. The method of obtaining the corresponding two-dimensional code or the bar code according to the management data may be implemented by any suitable technology that exists currently or becomes known in the future.

It should be understood that the examples discussed above are provided merely for the purpose of disclosing various embodiments, and are not intended to limit the scope of the present invention. In addition to the NFC label, the RFID label, and the two-dimensional code, a person skilled in the art may use various other forms or types of labels within the scope of the present invention, as long as the management data included in the label can be extracted by the electronic device.

In step 420, the method includes arranging the label in relation to a portion of a supporting component or of a stripe of the rack.

According to various embodiments of the present invention, the label provided in the step 410 may be arranged in many manners. The step 420 is a specific implementation manner of arranging a label. Details related to the step 420 may be obtained with reference to the embodiment shown in FIG. 2. It should be noted that, for the method 400, the step 420 is merely an optional step. In a case without the step 420, the method 400 for providing the label may also be implemented.

Additionally, in one embodiment, the label may be arranged together with an identifier, the identifier is used for marking the portion of the supporting component or stripe, and related details may be obtained with reference to the embodiment shown in FIG. 3.

According to a further embodiment of the present invention, the management data stored in, or represented by, the label may be updated in response to a change of at least one of the rack, the mounting assembly, and the electronic device. This change may, for example, include moving a rack from one machine room to another machine room, adding or removing a mounting assembly, replacing an electronic device with another electronic device, and other changes related to the rack, the mounting assembly, or the electronic device. In the case of moving the rack, the rack identifier, the location, the maintainer and other information in the management data may be updated. In the case of adding or removing the mounting assembly, the mounting assembly identifier, the location, the maintainer and the like in the management data may be updated. In the case of replacing the electronic device, the identifier, the location, the IP address, the MAC address, the maintainer, the suggested power limitation, the suggested I/O throughput limitation, the suggested thermal protection threshold, and the like of the electronic device in the management data may be updated.

According to different label types, there may be various processes for updating the management data. In one embodiment of updating the management data, a label writer may be used to write an updated part or all management data into the NFC label or the RFID label. The label writer may be implemented by using a dedicated device, and may also be implemented by using an existing device. For example, the management data of the label may be updated by using a terminal (such as a mobile phone and a tablet computer) having an NFC or RFID writing function. In another embodiment, a new two-dimensional code or bar code may be generated based on the updated management data by using a two-dimensional code or bar code generating device, and the new two-dimensional code or bar code may cover the original two-dimensional code or bar code.

It should be understood that the above descriptions are examples for updating the management data of the label, and are used merely for discussion, instead of limiting the present invention. It should be further understood that updating the management data is optional for the method 400, and is not necessary.

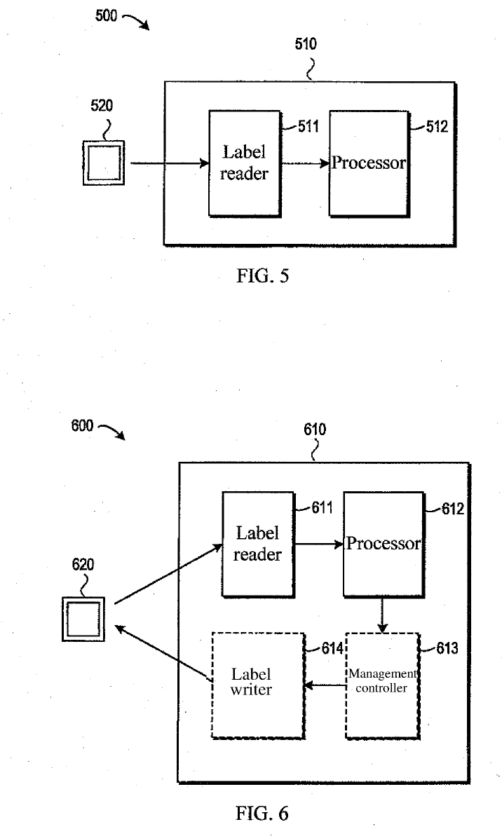

FIG. 5 is a block diagram 500 of an electronic device 510 according to an embodiment of the present invention. The electronic device 510 and a label 520 are schematically shown. According to one embodiment of the present invention, the electronic device 510 may be a server (computer), a router, an exchanger, a switcher (for example, a keyboard video mouse (KVM) switcher), a monitor, a storage device, a power supply device, or any other related device that can be used within a rack. As shown, the label 520 does not belong to the electronic device 510, but belongs to a rack (not shown). The label 520 is associated with a mounting assembly of the rack, and includes management data related to at least one of the rack, the mounting assembly, and the electronic device. Accordingly, the label 520 may be disposed on the rack or outside the rack. The label 520 may be implemented in various manners. For example, the label may include an NFC label, an RFID label, a two-dimensional code such as a bar code, and/or any other label in a suitable form.

According to the embodiment shown in FIG. 5, the electronic device 510 may acquire management data from the label in various ways. In one embodiment, when the electronic device 510 is mounted on the rack, for example, in a process of putting the electronic device 510 into the rack, the electronic device 510 may acquire information related to the label from the label 520 of the rack, thereby determining the management data from the information of the label. In an alternative embodiment, after the electronic device 510 is mounted on the rack, when the electronic device 510 is started or rebooted, the electronic device 510 may acquire the management data from the label. In another alternative embodiment, after the electronic device 510 is mounted on the rack, the electronic device 510 may acquire the management data from the label at a predetermined time interval (such as, one day, one week, or one year). It should be understood that the above examples are merely used for discussion instead of limiting the scope of the present invention. In addition to the above embodiment, the electronic device 510 may also select an opportunity of acquiring the management data from the label according to a specific situation.

In the embodiment shown in FIG. 5, the electronic device 510 may include a label reader 511 and a processor 512. The label reader 511 may be configured to acquire information from the label associated with the mounting assembly of the rack, where the mounting assembly defines a space for accommodating the electronic device 510. In this disclosure, the processor 512 may also be referred to as a label processor 512. The processor 512 may be configured to determine the management data based on the information acquired from the label 520. The management data is preferably related to at least one of the rack, the mounting assembly, and the electronic device 510. In various embodiments of the present invention, the management data may include an identifier, a location, a maintainer, an IP address, an MAC address, a suggested power limitation, a suggested I/O throughput limitation, a suggested thermal protection threshold, and any other suitable data about the rack, the mounting assembly and/or the electronic device. Additionally or optionally, the management data may also include information about the label, such as a first creation time, an update time, and a version.

The label reader 511 of the electronic device 510 may be implemented in many manners. In one embodiment, the label reader 511 may include a signal transceiver. The signal transceiver may be configured to send a first signal to the label, and to receive, from the label, a second signal triggered by the first signal. In this embodiment, the processor 512 of the electronic device 510 may be further configured to determine management data based on the second signal. The management data may be preset by the user according to environment requirements, system conditions and the like. In this manner, the electronic device 510 may extract the management data from the label 520 such as an NFC label and an RFID label, so that the user can manage the electronic device more effectively and conveniently.

In a further alternative embodiment, the label reader 511 of the electronic device 510 may include a scanner, and the scanner may be configured to acquire an image of the label. In this embodiment, the processor 512 of the electronic device 510 may be further configured to extract a feature from the image of the label, and determine the management data based on the extracted feature. In this manner, the electronic device 510 may extract the management data from the label 520 such as a two-dimensional code, so that the user can manage the electronic device more effectively and conveniently. According to various embodiments of the present invention, in addition to the label reader and the processor, the electronic device 510 may further include other suitable members or apparatuses.

FIG. 6 is a block diagram 600 of an electronic device 610 according to another embodiment of the present invention. In the block diagram 600, the electronic device 610 and a label 620 are shown. The electronic device 610 may be considered as a specific embodiment of the electronic device 510, and includes a label reader 611, a processor 612, a management controller 613, and a label writer 614. The label 620 may be a label similar to the label 520. It should be understood that the management controller 613 and the label writer 614 are merely optional for the electronic device according to the present invention, and are not necessary. This embodiment is shown merely for the purpose of discussion, and is not intended to limit the scope of the present invention in any manner.

In the embodiment of FIG. 6, the label reader 611 and the processor 612 are similar to the label reader 511 and the processor 512 shown in FIG. 5. The label reader 611 may be configured to acquire information from the label associated with a mounting assembly of a rack, where the mounting assembly defines a space for accommodating the electronic device 610. The processor 612 may be configured to determine management data based on the information acquired from the label 620.

According to the embodiment shown, the management controller 613 may be configured to acquire management data from the processor 612, and update a configuration of the electronic device 610 by using the management data. In an embodiment, the management controller 613 may, for example, send a request to the processor 612 to request the processor 612 for the management data. When receiving the request, the processor 612 knows that the management controller 613 intends to acquire the management data, and then sends the management data to the management controller 613 in response to the request. In another embodiment, the processor 612 may provide the management data to the management controller 613 periodically, so that the management controller 613 can acquire the management data from the processor 612 without the need of sending any request.

The configuration of the electronic device may be initialized when being manufactured, for example, a power limitation, an I/O throughput limitation, a thermal protection threshold and the like of the electronic device may be initialized. After acquiring the management data, the management controller 613 may update the configuration of the electronic device by using the acquired management data. For example, the power limitation, the I/O throughput limitation and the thermal protection threshold in the current configuration may be replaced with a suggested power limitation, a suggested I/O throughput limitation, and a suggested thermal protection threshold in the management data, and/or information such as the location, the maintainer, and the owner of the rack in the management data may be added to the current configuration of the electronic device.

Additionally or optionally, in another embodiment, the management controller 613 may be further configured to send the management data to a management server. The management server may be, for example, a remote device, which communicates with one or more electronic devices, and performs management and control on the electronic devices by using the management data received from the electronic devices.

Additionally or optionally, in yet another embodiment, the management controller 613 may be coupled with a main operating system (OS). The main OS may be a major operating system running in the electronic device 610, for example, Linux, Unix, WindowsServer, or the like. In addition to the main OS, the electronic device 610 may also have other operating systems, which is not described in detail here. The management controller 613 may be further configured to send the management data to the main OS in response to receiving a label identification request from the main OS. In this embodiment of the present invention, the label identification request may be sent by the main OS to the management controller to cause the management controller to provide the management data. In an embodiment, when the management controller receives the label identification request sent by the main OS, the management controller 613 may transmit to the main OS the management data that has been acquired from the processor 612. In another embodiment, when receiving the label identification request from the main OS, the management controller 613 may send a request to the processor 612 in response to the label identification request, so as to perform identification of the label. The processor 612 may command, according to the request from the management controller 613, the label reader 611 to read information of the label 620, acquire the management data from the information of the label 620, and send the acquired management data to the management controller 613. Therefore, the management controller 613 may send the management data to the main OS.

In one embodiment, the management controller 613 may further be configured to determine updated data based on configuration of the electronic device 610. For example, the configuration of the electronic device 610 may include, for example, dynamic address information of the electronic device 610, such as a dynamically distributed IP address and a dynamically distributed MAC address. The management controller 613 may determine the dynamic address information of the electronic device 610 as the updated data, so as to update the management data in the label.

In a further embodiment, the electronic device 610 may include a label writer 614, and the label writer 614 may be configured to write into the label 620 the updated data determined by the management controller 613, so as to update the management data. In this manner, the management data in the label 620 may be updated to include the latest IP address, the latest MAC address and the like of the electronic device, so as to facilitate management and tracing of the electronic device.

It should be understood that the management controller 613 and the label writer 614 are optional components for the electronic device, and are not necessary. Moreover, for clarity, other optional components of the electronic device 610 are not shown in FIG. 6. However, it should be understood that the electronic device 610 may include various other suitable components, and is not limited to the specific embodiment shown in FIG. 6.

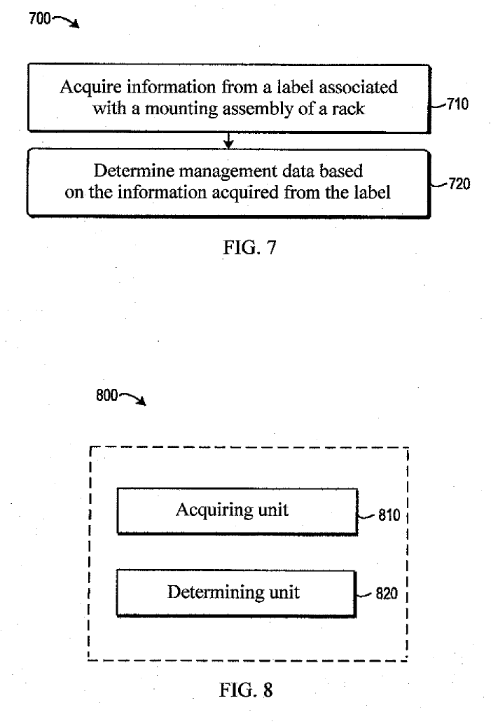

FIG. 7 is a block diagram of a method 700 executed by an electronic device according to an embodiment of the present invention. The electronic device executing the method 700 may be, for example, the electronic device 510 shown in FIG. 5, the electronic device 610 shown in FIG. 6, or another electronic device in a suitable form according to embodiments of the present invention.

In step 710, information is acquired from a label associated with a mounting assembly of a rack. The rack may be, for example, the rack shown in FIG. 1. The mounting assembly of the rack defines a space used for accommodating the electronic device, and the label of the rack is associated with the mounting assembly and includes management data related to at least one of the rack, the mounting assembly, and the electronic device. The information may be acquired from the label in many manners. In one embodiment, the label of the rack may be, for example, an NFC label or an RFID label, and in this case, the electronic device may send a first signal to the label, and receive from the label a second signal triggered by the first signal. In an alternative embodiment, the label of the rack may be a two-dimensional code, such as a bar code, such that the information acquired by the electronic device from the label may include an image of the label. In other words, the image of the label may be acquired in step 710.

In step 720, management data is determined based on the information acquired from the label. The management data may be related to at least one of the rack, the mounting assembly, and the electronic device. In one embodiment, when the first signal is sent to the label of the rack and the second signal, from the label and triggered by the first signal, is received in step 710, the management data may be determined based on the received second signal in step 720. In an alternative embodiment, after the image of the label is acquired in step 710, step 720 extracts a feature from the image of the label, and the management data is determined based on the extracted feature.

Additionally or optionally, configuration of the electronic device may be updated by using the management data. The configuration of the electronic device may be initialized when being manufactured, and may be updated during use. For example, the power limitation, the I/O throughput limitation and the thermal protection threshold in the current configuration may be replaced with a suggested power limitation, a suggested I/O throughput limitation, and a suggested thermal protection threshold in the management data, and/or information such as the location, the maintainer, and the owner of the rack in the management data may be added to the current configuration of the electronic device.

Additionally or optionally, the management data may be sent to a management server. The management server may be, for example, a remote device, which may communicate with one or more electronic devices, and perform management and control on the electronic devices by using the management data received from the electronic devices.

Additionally or optionally, updated data may be determined based on the configuration of the electronic device. For example, the configuration of the electronic device may include, for example, dynamic address information of the electronic device, such as a dynamically distributed IP address and a dynamically distributed MAC address. The management controller may determine the dynamic address information of the electronic device as the updated data, and write the updated data into the label, so as to update the management data in the label.

FIG. 8 is a block diagram of an apparatus 800 in an electronic device according to an embodiment of the present invention. As shown in the drawing, the apparatus 800 includes an acquiring unit 810, configured to acquire information from a label associated with a mounting assembly of a rack, and a determining unit 820, configured to determine management data based on the information acquired from the label.

In one embodiment, the acquiring unit 810 may include a signal sending unit that is configured to send a first signal to the label, and a signal receiving unit that is configured to receive, from the label, a second signal triggered by the first signal. The determining unit 820 may include a management data determining unit that is configured to determine management data based on the second signal.

In another embodiment, the acquiring unit 810 may include an image collecting unit that is configured to acquire an image of the label. Accordingly, the determining unit 820 may include a feature extracting unit that is configured to extract a feature from the image of the label, and a management data determining unit that is configured to determine management data based on the extracted feature.

Optionally, the apparatus 800 may further include an updating unit that is configured to update configuration of the electronic device by using the management data.

In yet another embodiment, the apparatus 800 may further include a management data sending unit that is configured to send the management data to a management server.

In still another embodiment, the apparatus 800 may further include an updated data determining unit that is configured to determine updated data based on the configuration of the electronic device, and a data writing unit that is configured to write the updated data into the label and update the management data in the label.

For clarity, optional units included in the apparatus 800 and sub-units included in the units are not shown in FIG. 8. It should be understood that the apparatus 800 may be implemented in many manners. For example, in some embodiments, the apparatus 800 may be implemented by using software and/or firmware. For example, the apparatus 800 may be implemented as a computer program product included in a computer readable medium, where each unit is a program module implementing a function thereof by using a computer instruction. Alternatively or additionally, the apparatus 800 may be implemented partially or completely based on hardware. For example, the apparatus 800 may be implemented as an integrated circuit (IC) chip, an application specific integrated circuit (ASIC), or a system on chip (SOC). Other manners that are currently known or will be developed in the future are also available, and the scope of the present invention is not limited in this aspect.

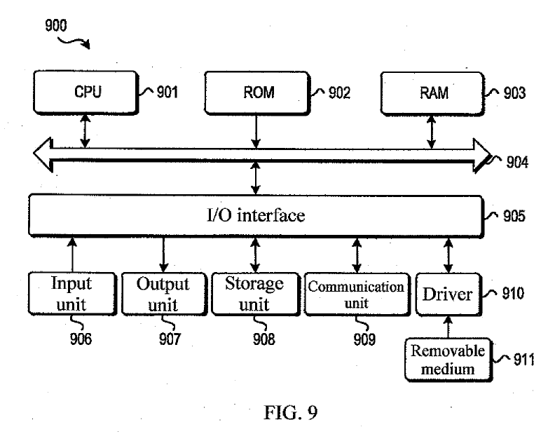

FIG. 9 is a schematic block diagram of an exemplary computer system 900 that is suitable for implementing various embodiments of the electronic device of the present invention. As shown in the drawing, the computer system 900 includes a central processing unit (CPU) 901, which may execute various suitable actions and processing according to a program stored in a read-only memory (ROM) 902 or a program loaded from a storage unit 908 to a random access memory (RAM) 903. The RAM 903 further stores data required by the CPU 901 to execute various processing. The CPU 901, the ROM 902 and the RAM 903 are connected to each other through a bus 904. An input/output (I/O) unit 905 is also connected to the bus 904.

The following members are connected to the I/O interface 905: an input unit 906 that may include a keyboard, a mouse, or similar input devices; an output unit 907 that may include a cathode ray tube (CRT), a liquid crystal display (LCD), speakers, and similar output devices; a storage unit 908 that may include a hard disk, flash drive or similar storage devices; and a communication unit 909 that may include a network interface card such as an LAN card or a modem. The communication unit 909 executes communication processing through a network such as the Internet. A driver 910 may also be connected to the I/O interface 905. A removable medium 911, such as a magnetic disk, an optical disc, a magnetic optical disk, and a semiconductor memory, may be mounted on the driver 910 as needed, so that a computer program read therefrom may be installed into the storage unit 908.

Particularly, according to various embodiments of the present invention, the above-described processes may be implemented as computer software programs. For example, embodiments may include a computer program product, which includes a computer program physically included on a machine readable medium, and the computer program includes program code causing a processor to execute the methods. In such an embodiment, the computer program may be downloaded from the network through the communication unit 909 and then installed, and/or may be installed from the removable medium 911.

Generally speaking, various exemplary embodiments of the present invention may be implemented in hardware or a dedicated circuit, software, logic, or any combination thereof. Some aspects may be implemented in hardware, and other aspects may be implemented in firmware or software executed by a controller, a microprocessor or another computing device. When various aspects of the embodiment of the present invention are shown or described as block diagrams, flowcharts or indicated by using some other graphics, it is understood that the block, apparatus, system, technology or method described herein may be implemented as non-limiting examples in the hardware, software, firmware, dedicated circuit or logic, general purpose hardware or controller or another computing device, or some combinations thereof.

Moreover, the blocks in the flowchart may be considered as method steps, and/or operations generated by operations of the computer program codes, and/or understood as multiple coupled logic circuit elements executing related functions. For example, the embodiment of the present invention includes a computer program product, the computer program product includes a computer program physically included on a machine readable medium, and the computer program includes program codes configured to implement the above-described methods.

In the context of the disclosure, the machine readable medium may be any physical medium including or storing programs used for or related to an instruction execution system, apparatus or device. The machine readable medium may be a machine readable signal medium or a machine readable storage medium. The machine readable medium may include, but is not limited to, an electronic, magnetic, optical, electromagnetic, infrared, or semiconductor system, apparatus or device, or any suitable combination thereof. The more detailed example of the machine readable storage medium includes: an electric connection provided with one or more leads, a portable computer magnetic disk, a hard disk, a random access memory (RAM), a read only memory (ROM), an erasable and programmable read only memory (EPROM or flash memory), an optical storage device, a magnetic storage device, or any suitable combination thereof.

The computer program codes used for implementing the method of the present invention may be written in one or more programming languages. The computer program codes may be provided to a processor of a general purpose computer, a dedicated computer, or another programmable data processing apparatus, so that when the program codes are executed by the computer or the other programmable data processing apparatus, functions/operations specified in the flowchart and/or block diagram are implemented. The program codes may be executed completely on the computer, partially on the computer, as an independent software packet, partially on the computer and partially on a remote computer, or completely on a remote computer or a server.

In addition, the operations are described in a specific order. However, it should not be considered as that these operations need to be implemented in the specific order shown or in a successive order, or that all shown operations are executed to acquire an expected result. In some situations, multiple tasks or parallel processing is beneficial. Likewise, the above discussion includes some specific implementation details, but the discussion should not be considered as limiting the scope of the present invention or claims, but should be considered as descriptions of specific embodiments directed to the specific invention. Some features described in the context of separated embodiments in the specification may also be integrated and implemented in a single embodiment. On the contrary, various features described in the context of a single embodiment may also be implemented separately in multiple embodiments or in any suitable sub-combination.

Various modifications and variations directed to the exemplary embodiments of the present invention will be more obvious for persons skilled in the art when the above descriptions are viewed together with the accompanying drawings. Any and all modifications still fall within the scope of non-limitative and exemplary embodiments of the present invention. Moreover, the above specification and accompanying drawings have inspiring benefits, and persons skilled in the art related to the embodiments of the present invention will derive other embodiments of the present invention illustrated herein.

It should be understood that the embodiments of the present invention is not limited to the disclosed specific embodiments, and modifications and other embodiments shall fall within the scope of the accompanying claims. Specific terms are used herein; however, the terms are merely used in general and descriptive meanings, and are not used for limiting.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable storage medium(s) may be utilized. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device. Furthermore, any program instruction or code that is embodied on such computer readable storage medium (including forms referred to as volatile memory) is, for the avoidance of doubt, considered “non-transitory”.

Program code embodied on a computer readable storage medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, and/or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored as non-transitory program instructions in a computer readable storage medium that can direct a computer, other programmable data processing apparatus, or other devices to function in a particular manner, such that the program instructions stored in the computer readable storage medium produce an article of manufacture including non-transitory program instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A rack, comprising:
a mounting assembly defining a space used for accommodating an electronic device; and
a label associated with the mounting assembly and including management data related to at least one of the rack, the mounting assembly, and the electronic device.

2. The rack of claim 1, further comprising:
a supporting component or a stripe, wherein the label is arranged in relation to a part of the supporting component or a part of the stripe.

3. The rack of claim 2, wherein the part of the supporting component or the part of the stripe is marked by an identifier, and wherein the label is arranged together with the identifier.

4. The rack of claim 1, wherein the management data includes at least one item of information selected from an identifier, a location, a maintainer, an IP address, a media access control address, a suggested power limitation, a suggested input/output throughput limitation, and a suggested thermal protection threshold.

5. The rack of claim 1, wherein the label is selected from a near field communication label, a radio frequency identification label, a two-dimensional code, and combinations thereof.

6. A method, comprising:
providing a label associated with a mounting assembly of a rack, wherein the mounting assembly defines a space used for accommodating an electronic device, wherein the label comprises management data extractable by the electronic device, and wherein the management data relates to at least one of the rack, the mounting assembly, and the electronic device.

7. The method of claim 6, further comprising:
arranging the label in relation to a part of a supporting component or a stripe of the rack.

8. The method of claim 7, further comprising:
arranging the label together with an identifier used for marking the part of the supporting component or the stripe.

9. The method of claim 6, further comprising:
updating the management data in response to a change of at least one of the rack, the mounting assembly, and the electronic device.

10. The method of claim 6, wherein the management data includes at least one item of information selected from an identifier, a location, a maintainer, an internet protocol address, a media access control address, a suggested power limitation, a suggested input/output throughput limitation, and a suggested thermal protection threshold.

11. The method of claim 6, wherein the label is selected from a near field communication label, a radio frequency identification label, a two-dimensional code, and combinations thereof.

12. An electronic device, comprising:
a label reader configured to acquire information from a label associated with a mounting assembly of a rack, wherein the mounting assembly defines a space for accommodating the electronic device; and
a processor configured to determine management data based on the information acquired from the label, wherein the management data is related to at least one of the rack, the mounting assembly, and the electronic device.

13. The electronic device of claim 12, wherein the label reader includes a signal transceiver configured to send a first signal to the label and to receive, from the label, a second signal triggered by the first signal, and wherein the processor is further configured to determine the management data based on the second signal.

14. The electronic device of claim 12, wherein the label reader includes a scanner configured to acquire an image of the label, and wherein the processor is further configured to extract a feature from the image of the label and determine the management data based on the extracted feature.

15. The electronic device of claim 12, further comprising:
a management controller configured to acquire the management data from the processor and update configuration of the electronic device by using the management data.

16. The electronic device of claim 15, wherein the management controller is further configured to send the management data to a management server.

17. The electronic device of claim 15, wherein the management controller is coupled with a main operating system, and wherein the management controller is further configured to send the management data to the main operating system in response to receiving a label identification request from the main operating system.

18. The electronic device of claim 12, further comprising:
a management controller configured to determine updated data based on the configuration of the electronic device; and
a label writer configured to write the updated data into the label to update the management data.

19. The electronic device of claim 12, wherein the management data includes at least one item of information selected from an identifier, a location, a maintainer, an internet protocol address, a media access control address, a suggested power limitation, a suggested input/output throughput limitation, and a suggested thermal protection threshold.

20. The electronic device of claim 12, wherein the label is selected from a near field communication label, a radio frequency identification label, a two-dimensional code, and combinations thereof.
